(19) United States
(12) Patent Application Publication
(10) Pub. No.: US 2024/0055298 A1
(43) Pub. Date: Feb. 15, 2024

(54) PLASMA-SINGULATED, CONTAMINANT-REDUCED SEMICONDUCTOR DIE

(71) Applicant: SEMICONDUCTOR COMPONENTS INDUSTRIES, LLC, Scottsdale, AZ (US)

(72) Inventors: JeongPyo HONG, Bucheon (KR); Mohd Akbar MD SUM, Kajang (MY); Gordon M. GRIVNA, Mesa, AZ (US)

(73) Assignee: SEMICONDUCTOR COMPONENTS INDUSTRIES, LLC, Scottsdale, AZ (US)

(21) Appl. No.: 18/490,923

(22) Filed: Oct. 20, 2023

Related U.S. Application Data
(62) Division of application No. 16/948,709, filed on Sep. 29, 2020.
(60) Provisional application No. 62/924,664, filed on Oct. 22, 2019.

(51) Int. Cl. H01L 21/78; H01L 21/67; H01L 21/3065; H01L 23/00

(52) U.S. Cl. CPC H01L 21/78; H01L 21/67069; H01L 21/3065; H01L 23/564

(57) ABSTRACT

Described implementations include a contaminant-free plasma singulation process, in which residues of materials used during plasma singulation are fully removed from sidewalls of a resulting semiconductor die, without damaging the semiconductor die. From such a contaminant-free plasma singulation process, a semiconductor die may be manufactured. The semiconductor die may include a first plurality of sidewall recesses formed in a sidewall of a substrate of the semiconductor die between a first surface and a second surface of the substrate, each having at most a first depth, as well as a second plurality of sidewall recesses formed in the sidewall of the substrate and disposed between the first plurality of sidewall recesses and the second surface, each having at least a second depth that is greater than the first depth.

### CROSS-REFERENCE TO RELATED APPLICATION

This application is a divisional application of U.S. patent application Ser. No. 16/948,709, filed Sep. 29, 2020, which claims priority to and the benefit of and priority to U.S. Provisional Application No. 62/924,664, filed Oct. 22, 2019, these applications are incorporated by reference herein in their entireties.

### TECHNICAL FIELD

This description relates to plasma-singulated semiconductor die.

### BACKGROUND

Individual semiconductor die are typically singulated from a wafer on which the semiconductor die were formed. Multiple types of die singulation techniques exist to singulate semiconductor die, including mechanical cutting using a saw, laser separation, and plasma singulation.

In plasma singulation, die singulation occurs using an etching process. The etching process can be performed using a chemistry that selectively etches silicon at a much higher rate than that of dielectrics and/or metals. Plasma singulation provides a number of advantages compared to other singulation techniques, such as supporting narrower scribe lines, providing increased throughput, and providing an ability to singulate die in varied and flexible patterns.

### SUMMARY

According to one general aspect, a semiconductor die includes a substrate having a first surface and a second surface that is opposed to the first surface, and a first plurality of sidewall recesses formed in a sidewall of the substrate between the first surface and the second surface, each having at most a first depth. The semiconductor die includes a second plurality of sidewall recesses formed in the sidewall of the substrate and disposed between the first plurality of sidewall recesses and the second surface, each having at least a second depth that is greater than the first depth.

According to another general aspect, a semiconductor die includes a substrate having a first surface and a second surface that is opposed to the first surface, and a first plurality of sidewall recesses formed in a sidewall of the substrate and extending along a first length of the sidewall from the first surface, the first plurality of sidewall recesses each defining at most a first depth. The semiconductor die also includes a second plurality of sidewall recesses formed in the sidewall of the substrate and extending along a second length of the sidewall between the first plurality of sidewall recesses and the second surface, the second plurality of sidewall recesses each defining at least a second depth that is greater than the first depth.

According to another general aspect, a method of making a semiconductor die includes forming a first plurality of sidewall recesses in a sidewall of a substrate and extending along a first length of the sidewall from a first surface of the substrate, the first plurality of sidewall recesses each defining at most a first depth. The method further includes forming a second plurality of sidewall recesses in the sidewall of the substrate and extending along a second length of the sidewall between the first plurality of sidewall recesses and a second surface of the substrate, the second plurality of sidewall recesses each defining at least a second depth that is greater than the first depth.

The details of one or more implementations are set forth in the accompanying drawings and the description below. Other features will be apparent from the description and drawings, and from the claims.

### BRIEF DESCRIPTION OF THE DRAWINGS

FIG. 1 illustrates a simplified side view of two semiconductor die during a contaminant-reduced plasma singulation process.

FIG. 2 illustrates the two semiconductor die of FIG. 1, following completion of the contaminant-reduced plasma singulation process of FIG. 1.

FIG. 3 is a top view of a semiconductor wafer prior to undergoing the contaminant-reduced plasma singulation process of FIG. 1.

FIG. 4 is a side view of the semiconductor wafer of FIG. 3.

FIG. 5 is a side view of the semiconductor wafer of FIG. 3, during an intermediate process step of the contaminant-reduced plasma singulation process of FIG.

FIG. 6 is an image of two semiconductor die produced using the contaminant-reduced plasma singulation process of FIG. 1.

FIG. 7 is a first flowchart illustrating example operations for implementing the contaminant-reduced plasma singulation process of FIG. 1.

FIG. 8 is a second flowchart illustrating example operations for implementing the contaminant-reduced plasma singulation process of FIG. 1.

### DETAILED DESCRIPTION

As described in detail below, embodiments include a contaminant-free plasma singulation process, in which residues of materials used during plasma singulation are fully removed from sidewalls of a resulting semiconductor die, without damaging the semiconductor die. Such contaminants, if not removed, may reduce a quality and reliability of a singulated die.

For example, plasma singulation may be implemented using a deep reactive ion etching (DRIE) process. During a DRIE process, fluorine and carbon polymers (s) (e.g., CIF's) may be deposited and used to form a passivation layer that facilitates the directional etching used to separate adjacent die. Although the DRIE process is designed to also etch away the fluorine and carbon polymers on horizontal surfaces, as described in more detail, below, residual contaminants typically remain on the sidewalls of the semiconductor die, and must be removed during one or more post-processing operations (e.g., while the die 102, 104 are still within a plasma dicing chamber, and/or following removal from the plasma dicing chamber).

For example, various techniques exist to use solvents and/or isotropic plasma etching to remove such residual contaminants. However, the use of such techniques is typically limited by effects of the removal on the semiconductor die, and/or on ancillary processing materials and structures. For example, use of such methods may result in unwanted separation of the semiconductor die from an underlying (backside) carrier tape, limiting the ability to remove such residual contaminants.

One reason for difficulties in removing contaminants from sidewalls of semiconductor die during and following plasma singulation is that included etching processes typically etch into the sidewalls, leaving sidewall recesses that are then filled with the fluorine and carbon polymers during subsequent processing steps. Recesses near the device-side surface of the semiconductor die are formed earlier than deeper recesses that are closer to the opposed surface of the semiconductor die. As a result, the earlier-formed recesses are exposed to a larger number of etching cycles, and tend to accumulate thicker layers of contaminants, which are subsequently more difficult to remove than contaminants that accumulate within the deeper recesses.

Therefore, implementations described herein use at least two processing cycles, to form at least two different types of sidewall recesses. A first processing cycle is executed with first processing parameters, and forms relatively shallow and/or narrow recesses near a device-side surface of a semiconductor die. A second processing cycle is executed with second processing parameters, and forms relatively deep and/or wide recesses farther from the device-side surface of the semiconductor die.

As a result, for example, relatively shallow and narrow recesses accumulate fewer and thinner residual contaminants, as compared to similarly-positioned recesses in conventional techniques. Accordingly, in described embodiments, processes for removing the contaminants are effective in removing the contaminants from all of the sidewall recesses.

Additionally, providing relatively shallow and narrow recesses in the area of the device-side surface of the semiconductor die consumes less of the substrate of the semiconductor die, as compared to conventional techniques, and therefore results in semiconductor die with more usable substrate area for forming semiconductor devices. Further, the substrate surface at the device-side of the substrate is more fully supported, since the underlying substrate is left more fully intact than in conventional techniques. The resulting semiconductor die provides increased stability at the top surface of the die as compared to conventional semiconductor die formed using conventional plasma singulation processes.

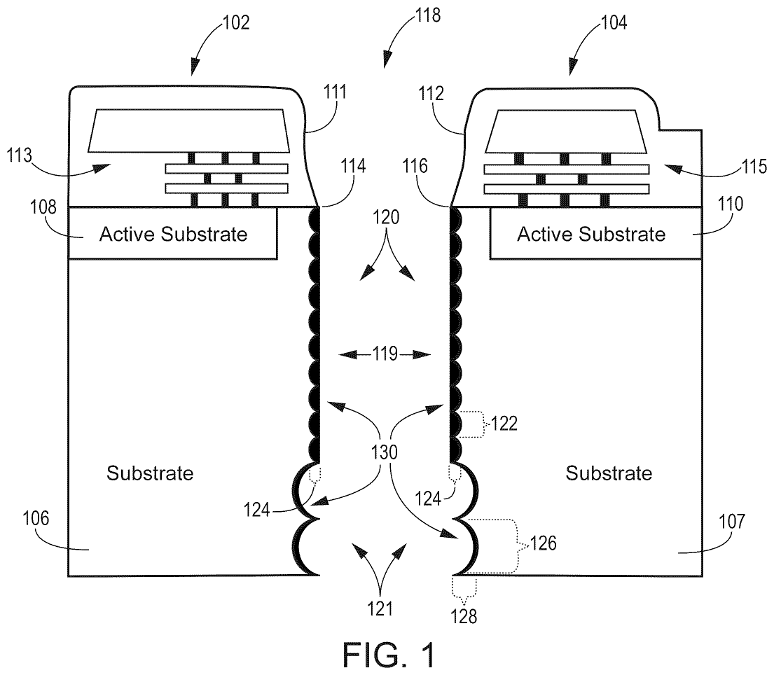

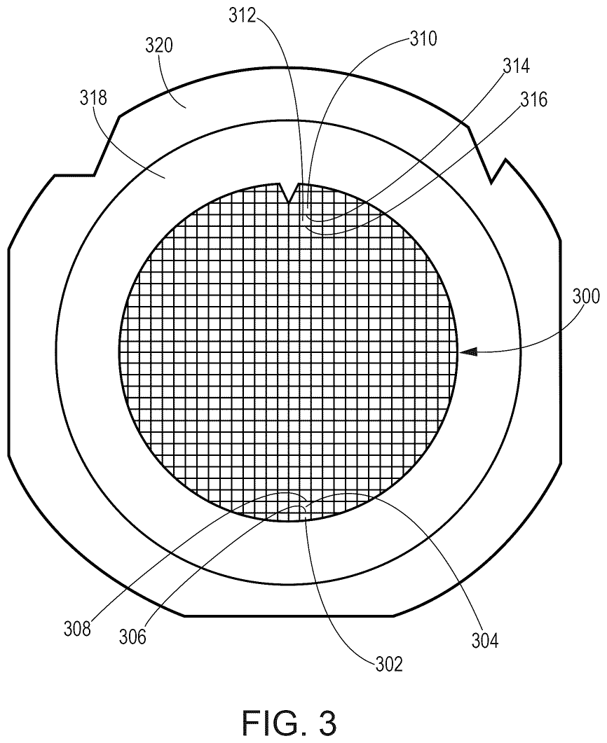

FIG. 1 illustrates a simplified side view of two semiconductor die during a contaminant-reduced plasma singulation process. In the example of FIG. 1, a first semiconductor die 102 and a second semiconductor die 104 are illustrated as including a substrate portion 106 and a substrate portion 107, respectively. As illustrated and described below, e.g., with respect to FIGS. 3-5, the substrate portions 106, 107 may be portions of a single semiconductor wafer that is being singulated using the plasma singulation processes described herein.

Further in the simplified example of FIG. 1, active area 108 in the semiconductor die 102, and active area 110 in the semiconductor die 104, represent active areas which may be used in conjunction with providing representative devices 113 and 115, respectively. As shown, the representative devices 113, 115 may be provided within masking layer portions 111 and 112, also respectively. The device 113 and the device 115 may represent virtually any semiconductor device, or group of devices, that may be formed in a semiconductor wafer and singulated using the techniques described herein. For example, the device 113 and the device 115 may include various types of transistors or diodes, and related circuit elements, such as capacitors and resistors.

Mask portion 111 and mask portion 112 of an original mask layer are, respectively, disposed over a device-side surface 114 of the semiconductor die 102, and over a device-side surface 116 of the semiconductor die 104. An opening 118 is formed through the mask portion 111 and the mask portion 112, which extends through a full depth of the illustrated substrate portion 106 and the substrate portion 107, and defines corresponding sidewalls 119 of the semiconductor die 102, 104. Thus, the sidewalls 119 extend between the device-side surfaces 114, 116 and second surfaces of the substrates opposite the device-side surfaces 114, 116 of the substrate portions 106, 107.

More particularly, the mask layer portions 111, 112 may remain following removal of portions of an original mask layer during front end fabrication processes, and prior to plasma singulation commencing. During such front end processes, the removal of the mask layer portions defines a plasma dicing channel(s) down to a substrate surface. The mask layer portions 111, 112 extend a minimum distance between the active areas 108, 110 and edges of the plasma dicing channel. This minimum distance protects against potential lateral substrate loss during dicing processes, at the cost of limiting valuable area(s) of the substrate from being used as portions of the active areas 108, 110. However, techniques described herein enable a reduction of this minimum distance, and therefore increase an area of the substrate 106, 107 that may be used as active areas 108, 110, resulting in more efficient use of the semiconductor die 102, 104.

Further, once the plasma dicing channel is formed as just referenced, a DRIE process may be used to execute the plasma singulation processes described herein. For example, a first processing cycle with first process parameters is implemented to form first sidewall recesses 120, and a second processing cycle with second process parameters may be implemented to form second sidewall recesses 121, within the opening 118.

As illustrated and described, the first sidewall recesses 120 are formed with the first process parameters selected to maintain a width 122 and/or depth 124, such that a corresponding width 126 and/or depth 128 of the second sidewall recesses formed using the second process parameters are greater than the width 122 and/or the depth 124, respectively.

In FIG. 1, residual contaminants 130 of a passivation layer formed using fluorine and carbon polymers are illustrated as being disposed within the various sidewall recesses 120, 121. As referenced above, and described in more detail, below with respect to FIGS. 3-5 and 8, during the DRIE process, a three-step processing cycle may be implemented in which (1) a passivation layer is deposited within a currently-existing extent of the opening 118, (2) a first etch is anisotropically executed to remove only a portion of the passivation layer between the sidewalls 119 (e.g., at a bottom of the currently-existing extent of the opening 118), and thereby expose the substrate without removing the passivation layer from any previously-formed sidewall recesses, and (3) a second etch is isotropically executed to etch the exposed substrate at the bottom of the currently-existing extent of the opening 118. As the second etch isotropically etches the exposed substrate, new, individual ones of the various sidewall recesses 120, 121 are formed. However, the second etch is not typically able to remove remaining portions of the passivation layer, thus leading to the presence of residual polymer contaminants, as described herein.

Repeating this three-step processing cycle multiple times (e.g., iterations, or loops) therefore results in progressive formation of the opening 118 and the sidewall recesses 121, 122, until the substrate portion 106 and the substrate portion 107 are completely separated (e.g., the opening 118 may reach a backside carrier tape, shown below but not visible in FIG. 1).

In particular, any sidewall recesses relatively closer to the device-side surfaces 114, 116 are exposed to many more iterations or loops of the described processing cycle than any sidewall recesses relatively farther from the device side surfaces 114, 116. In conventional techniques, as described, the result is that sidewall recesses closer to the device-side surfaces 114, 116 exhibit thicker layers of contaminants that are more difficult to remove during post-processing than layers of contaminants within sidewall recesses relatively farther from the device side surfaces 114, 116.

However, in FIG. 1, the first sidewall recesses 120 have width 122 and depth 124 that are substantially less than corresponding width 126 and depth 128 of the second sidewall recesses 121. As a result, the first sidewall recesses 120 are limited in the amount of contaminants that may be accumulated therein. Accordingly, it becomes possible to execute an effective removal of all or substantially all of the contaminants 130, e.g., using a suitable solvent and/or isotropic plasma ashing step.

For example, as described herein, the first sidewall recesses 120 may be formed with the above-described three-step processing cycle, but using first process parameters, while the second sidewall recesses 121 may be formed with the above-described three-step processing cycle, but using second process parameters. That is, the three-step processing cycle described above may first be implemented for a defined number of iterations of a first processing cycle, using the first process parameters, to thereby define a corresponding number of the first sidewall recesses 120. Then, the second sidewall recesses 121 may be formed using the described three-step processing cycle, but with the second process parameters. That is, the three-step processing cycle described above may be implemented again, but using the second process parameters, over a number of iterations needed to entirely separate the two semiconductor die 102, 104, and thereby define a corresponding number of the second sidewall recesses 121. It should be understood that for simplicity, FIG. 1 is shown with two separate sidewall recess depths but it should be understood that alternately, the depth of the recesses may be incrementally adjusted deeper with depth into the semiconductor substrate in a manner to both minimize polymer build-up and/or optimize process throughput.

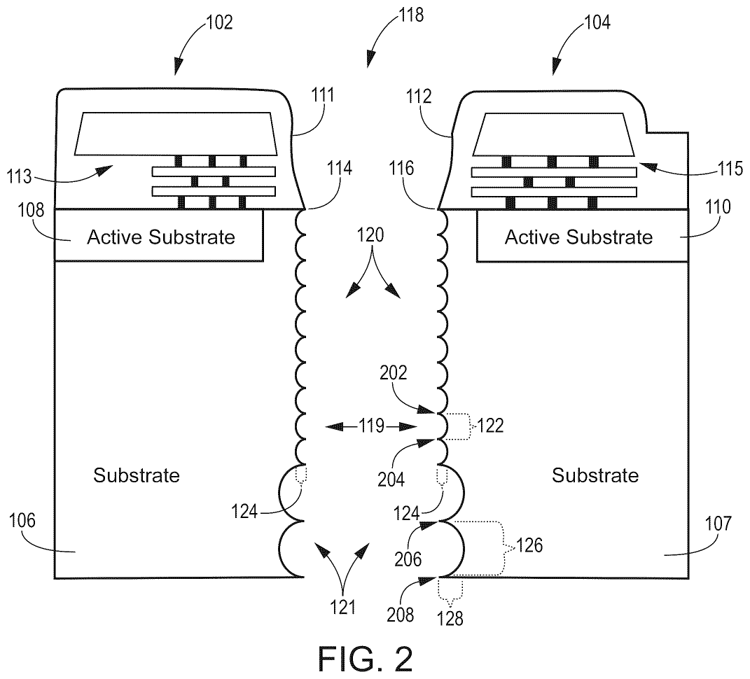

FIG. 2 illustrates the two semiconductor die of FIG. 1, following completion of the contaminant-reduced plasma singulation process of FIG. 1. As may be observed, contaminants 130 are removed, exposing the first sidewall recesses 120 and the second sidewall recesses 121.

FIG. 2 more clearly illustrates that the width 122 of the first sidewall recesses 120 may be defined as occurring between a first peak 202 and a second peak 204 that occurs between adjacent ones of the first sidewall recesses 120. Similarly, the width 126 of the second sidewall recesses 121 may be defined as occurring between a first peak 206 and a second peak 208 that occurs between adjacent ones of the second sidewall recesses 121. Meanwhile, the depth 124 of the first sidewall recesses and the depth 128 of the second sidewall recesses 121 may be defined, for example, with respect to the peaks 202-208.

FIG. 2 illustrates that a step increase in depth and/or width may be achieved between adjacent ones of the first sidewall recesses 120 and the second sidewall recesses 121. For example, at least one of the second plurality of sidewall recesses 121 may be adjacent to, and may have a depth at least twice that of, at least one of the first plurality of sidewall recesses 120.

In FIGS. 1-2, as well as with respect to following FIGS. 3-8, the sidewall recesses 120, 121 should be understood to describe any indentation or opening within sidewalls 119. For example, the sidewall recesses 120, 121 may represent concave surfaces with respect to the sidewalls 119 (e.g., with respect to the peaks 202/204, or 206/208), which have been hollowed out or rounded inward. As such, the sidewall recesses 120, 121 may form convex surfaces that are curved or rounded outward with respect to the substrate portions 106, 107. The sidewall recesses 120, 121 may also be referred to using terms of art, e.g., as scallops. The depth of the sidewall recesses 120, 121 also may be referred to as an undercut, or a scallop undercut.

FIG. 3 is a top view of a semiconductor wafer 300 prior to undergoing the contaminant-reduced plasma singulation process of FIG. 1. The wafer 300 includes a plurality of semiconductor die, such as die 302, 304, 310, and 312, that are formed on or as part of semiconductor wafer 300. Die 302, 304, 310, and 312 are spaced apart from each other on wafer 300 by spaces in which singulation lines are to be formed or defined, such as scribe lines or singulation lines 306, 308, 314, and 316. All of the semiconductor die on wafer 300 generally are separated from each other on all sides by areas where scribe lines or singulation lines, such as singulation lines 306, 308, 314, and 316 are to be formed. As already referenced, the die 302, 304, 310, and 312 can be any kind of electronic device including semiconductor devices, such as diodes, transistors, discrete devices, sensor devices, optical devices, integrated circuits or other devices known to one of ordinary skill in the art.

Further, in FIG. 3, the wafer 300 is mounted on carrier tape 318, which is attached to a suitable film frame 320. The carrier tape 318, which may also be referred to as transfer tape, may be supported by the film frame 320 during singulation, and may be used to support the plurality of die following singulation. Then, individual die (e.g., 302, 304, 310, and 312) may be separated from the carrier tape 318 for subsequent use thereof. For example, the carrier tape 318 may be an ultraviolet (UV) tape, that loses adhesion when exposed to UV light. Thus, the individual die 302, 304, 310, and 312 may be removed from the carrier tape 318 using, e.g., a pick-and-place tool. FIG. 3 is intended merely to provide examples, and other wafers, carrier techniques, and/or pre- or post-singulation techniques for transporting or otherwise performing wafer processing may also be used.

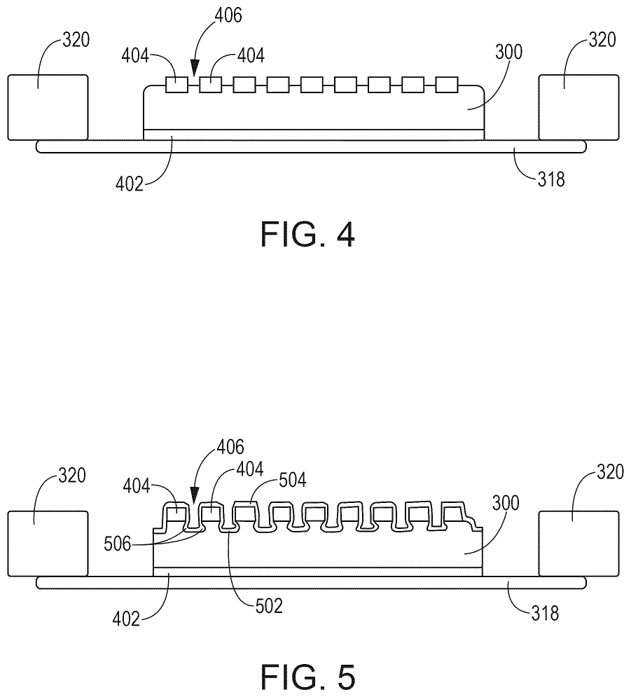

FIG. 4 is a side view of the semiconductor wafer of FIG. 3. In FIG. 4, the carrier tape 318 and film frame 320 are shown in side view, with the carrier tape 318 attached to the film frame 320, and to the wafer 300.

Further in FIG. 4, a conductive backside metal 402 is illustrated as being attached to the wafer 300, and to the carrier tape 318. As described below, the backside metal 402 may effectively serve as a stop for the described plasma singulation processes, including formation of the sidewall recesses 121, and portions of the backside metal 402 may remain attached to singulated semiconductor die at a completion of the singulation process, e.g., to serve as points of backside electrical contact for device(s) of each die. In other implementations, however, contacts may be provided using different techniques; for example, backside contact may not be required, or contacts may be provided following completion of the singulation process. In such cases, the backside metal 402 may be omitted.

In FIG. 4, mask portions 404 correspond to mask portions 111, 112 of FIG. 1, and define an opening 406 corresponding to the opening 118 of FIG. 1. In other words, the opening 406, and similar openings in FIG. 4, correspond to the various scribe lines 306, 308, 314, and 316 of FIG. 3.

FIG. 5 is a side view of the semiconductor wafer of FIG. 3, during an intermediate process step of the contaminant-reduced plasma singulation process of FIG. 1. As shown in FIG. 5, a portion 502 has been etched from the wafer 300, and a passivation layer 504 has been applied. Etched portions 506 thus define a first-formed sidewall recess corresponding to, or included in, the sidewall recesses 120.

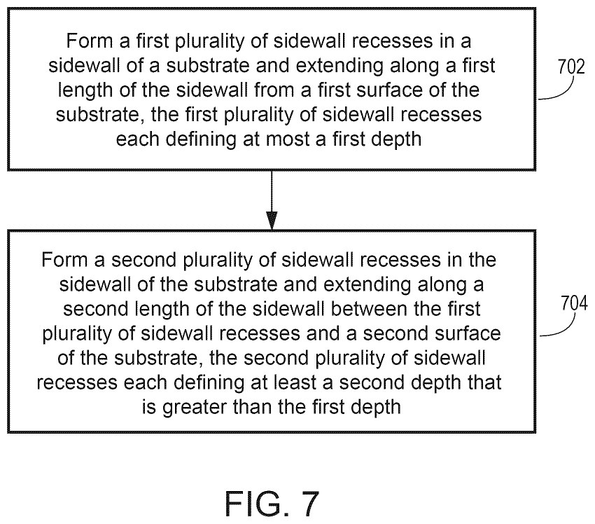

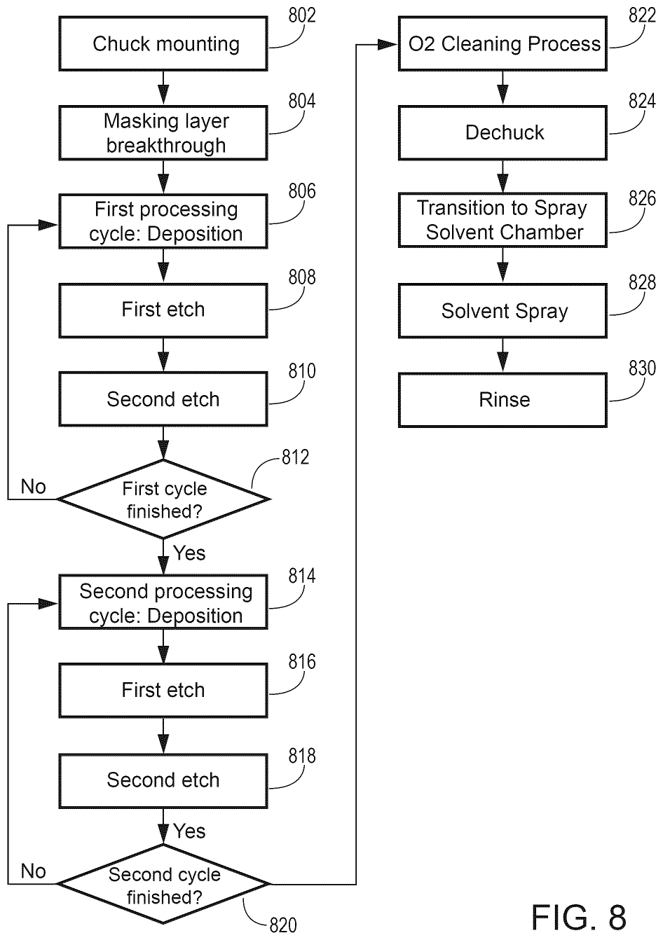

In subsequent processing steps, the passivation layer 504, and further portions of the wafer 300, may be etched preferentially from a bottom portion of the etched portion 502, thereby defining a second-formed sidewall recess of the sidewall recesses 120 (not shown in FIG. 5). This process is repeated iteratively, but adjusting process parameters as referenced above to distinguish the sidewall recesses 120 from the sidewall recesses 121. Examples of process parameter adjustments, and of the iterative processing in general, are described in more detailed examples with respect to FIGS. 7 and 8, below.

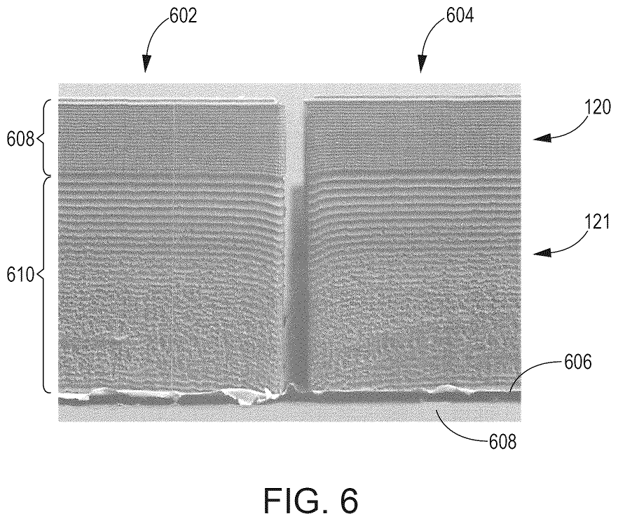

FIG. 6 is an image of two semiconductor die produced using the contaminant-reduced plasma singulation process of FIG. 1. In FIG. 6, a first semiconductor die 602 is singulated from a second semiconductor die 604, both of which are attached to back metal 606, which is itself attached to carrier tape 608. In some implementations, the back metal 606 may be omitted.

In FIG. 6, the first sidewall recesses 120 are defined along a first length 608 between a first (e.g., top) surface of the two semiconductor die 602, 604, while the second sidewall recesses 121 are formed along a second length 610 between a second, opposed (e.g., bottom, or backside) surface of the two semiconductor die 602, 604.

Thus, FIG. 6 a substrate, in which one or more semiconductor devices may be formed, as shown in FIG. 1, where each such substrate has a first surface (e.g., a device-side surface 114, 116 of FIG. 1). The first plurality of sidewall recesses 120 are formed in a sidewall of the substrate, each having at most a first depth. The second plurality of sidewall recesses 121 are formed in the sidewall of the substrate and disposed between the first plurality of sidewall recesses 120 and a second surface of the substrate opposite the first surface, each having at least a second depth that is greater than the first depth.

The first surface and second surface may be considered to form parallel, or approximately parallel, planes, so that the sidewall recesses 120, 121 generally extend in a direction perpendicular to the parallel planes. However, the sidewalls 119 may taper to some extent; e.g., may intersect with the parallel planes at non-perpendicular angles. As illustrated, the sidewall recesses 120 may be closer to the first, device-side surface, while the sidewall recesses 121 may be closer to the second surface, opposite the first surface.

In FIGS. 1 and 6, and in various examples described herein, described semiconductor die each have at least the two described pluralities of sidewall recesses 120, 121. In various implementations, however, there may be three or more pluralities of sidewall recesses. For example, each such plurality of sidewall recesses may have three or more corresponding processing cycles and corresponding process parameters implemented in distinct recess depth increases or variable non-distinct recess depth increases.

FIG. 7 is a first flowchart illustrating example operations for implementing an example embodiment of the contaminant-reduced plasma singulation process of FIG. 1.

In the example of FIG. 7, a first plurality of sidewall recesses are formed in a sidewall of a substrate, extending along a first length of the sidewall from a first surface of the substrate, the first plurality of sidewall recesses each defining at most a first depth (702). As shown in FIGS. 1, 2, and/or 6, the sidewall recesses 120 may define the first plurality of sidewall recesses (e.g., in FIG. 6, extending along the length 608 between a device-side surface of the die 602, 604 and the second plurality of sidewall recesses 121).

As referenced above, and described in more detail below with respect to FIG. 8, the first sidewall recesses 120 may be formed during a first processing cycle in which a plurality of processing steps are iteratively repeated, using first process parameters designed to yield formation of the first plurality of sidewall recesses 120 having at most a first depth and/or at most a first width (and thus, at most, a first three-dimensional volume). For example, as described below, one or more gas flow rates for one or more of etching or deposition gasses may be selected to limit the depth(s) of the sidewall recesses 120 to a maximum depth. Additionally, or alternatively, a processing time may be adjusted (e.g., reduced), or a processing power may be adjusted (e.g., reduced).

Then, a second plurality of sidewall recesses may be formed in the sidewall of the substrate, extending along a second length of the sidewall between the first plurality of sidewall recesses and a second surface of the substrate, the second plurality of sidewall recesses each defining at least a second depth that is greater than the first depth.

As also referenced above, and described in more detail below with respect to FIG. 8, the second sidewall recesses 121 may be formed during a second processing cycle in which a plurality of processing steps are iteratively repeated, using second process parameters designed to yield formation of the second plurality of sidewall recesses 121 having at least a second depth and/or at least a second width (and thus, at least, a second three-dimensional volume). For example, as referenced above and described below, one or more gas flow rates for one or more of etching or deposition gasses may be selected to ensure the depth(s) of the sidewall recesses 121 are at least a minimum depth. Additionally, or alternatively, a processing time may be adjusted (e.g., increased), or a processing power may be adjusted (e.g., increased).

FIG. 8 is a second flowchart illustrating example operations for implementing the contaminant-reduced plasma singulation process of FIG. 1. In FIG. 8, a wafer to be singulated, such as the wafer 300 of FIG. 3, is mounted on a mounting chuck (802). Then, a masking layer covering the wafer is broken through (804) along the lines of desired singulation. In this way, for example, the opening 118 of FIG. 1 may be formed between masking layer portions 111, 112, or the opening 406 between masking layer portions 404 of FIG. 4. In this way, any native oxide on the substrate surface may be removed during the just-referenced breakthrough step. As described with respect to FIG. 1, a portion of an original mask layer may be removed to define a plasma dicing channel during front end processes occurring prior to the DRIE processes described herein.

Then, a first processing cycle may commence (806), using first process parameters. As described above, the first processing cycle includes a deposition (806) of a passivation layer, such as the passivation layer 504 of FIG. 5. A first etching process is executed (808) to anisotropically etch away the passivation layer at a bottom portion of the opening. A second etching process is then executed (810) to isotropically etch portions of the substrate of the wafer being singulated. The second etch thus forms a pair of sidewall recesses.

The first processing cycle, if not finished (812), repeats. For example, during a second iteration of the first processing cycle, the passivation layer is deposited again (806), and the first etch is repeated (808), and then the second etch (810). As described, during the second etch, it may occur that some of the passivation layer is not fully removed from the first sidewall recess formed during the first iteration of the processing cycle. However, because the sidewall recesses 120 are relatively narrow and/or shallow, only a minimal amount of the passivation layer remains. As referenced above, and described in more detail, below, this minimal amount of remaining passivation layer may be more easily removed during a subsequent cleaning process (e.g., solvent spray and/or isotropic plasma etch process), again due to the nature of the relatively narrow and/or shallow sidewall recesses 120.

The first processing cycle may be repeated a designated number of iterations, or loops. For example, the first processing cycle may be repeated for 10, 15, 20, or 25 iterations, to form a corresponding number of the relatively narrow and/or shallow sidewall recesses 120 near a device side surface of the wafer being singulated. The number of iterations performed may be selected as a design parameter, e.g. to ensure that the sidewall recesses 120 extend along a designated length, portion, or percentage of the semiconductor die being formed, such as the length 608 of FIG. 6. As described, the length 608 may be chosen to obtain the advantages described herein, e.g., full removal of remnants of the passivation layer that would otherwise form contaminants within the sidewall recesses 120, 121. In the example embodiment using fixed depth for the first processing cycle, the depth 608 may form a distinct demarcation between the first step and second step, as shown in FIG. 6. Alternately, with increasing depth for the first cycle, the depth 608 may not be present.

Once the first processing cycle is finished (812) and the designated number of relatively narrow and/or shallow sidewall recesses 120 have been formed, a second processing cycle may begin to form remaining sidewall recesses 121, beginning with a deposition step (814). The second processing cycle continues as described above with respect to the first processing cycle, with a first, anisotropic etch (816) followed by a second, isotropic etch (818). If not finished (820), the second processing cycle continues (814, 816, 818) until the die are fully singulated; e.g., until a backside carrier tape (such at the carrier tape 318 of FIGS. 3-5 or the carrier tape 606 of FIG. 6) is reached (820). Then, the singulated die, e.g., still attached to the carrier tape, may be subjected to an O2 cleaning process (822), such as, e.g., an O2-based plasma ashing process. Such cleaning processes are typically insufficient to remove residual polymer contaminants, as already described.

Therefore, following a de-chuck from the mounting chuck (824), the singulated die may be isotropic plasma etch cleaned and/or transitioned to a spray solvent chamber for executing a spray solvent process (824). For example, the singulated die may be positioned on a spinning support member and positioned below a spray nozzle. Then, a solvent spray may be performed (826) by spinning the die while the nozzle sprays a suitable solvent, following by a rinse process (828) designed to rinse away any remaining solvent, carbon and fluorine polymers from the sidewall recesses 120, 121.

As described, this approach to post plasma dicing die sidewall cleaning is highly effective because contaminants in the sidewall recesses 120 are limited in thickness due to the narrow and/or shallow nature of the sidewall recesses, notwithstanding a proximity of the sidewall recesses 120 to the device side surface of the singulated die. Moreover, the etching processes and solvent cleaning processes do not compromise an integrity of adhesion of the singulated die to the carrier tape, so that the singulated die remain adhered to the carrier tape throughout the described processes.

Accordingly, known or future processes may be used to separate the singulated die from the carrier tape and place the separated, singulated die into desired locations (e.g., into suitable mounting or packaging).

It will be appreciated that the present description is provided by way of example, and encompasses many specific possible implementations, not all of which are explicitly described herein. For example, in some implementations, the sidewall recesses 120 may extend along a length 608 of FIG. 6 that is defined as a percentage (e.g., 105, 15%, 20%) of a total thickness (e.g., 608 and 610 combined) of the wafer being singulated, e.g., less than approximately twenty percent of the first length and the second length. For example, for a 100 micron wafer thickness, the sidewall recesses 120 may extend 15%, or 15 microns, while for a 150 micron wafer thickness, the sidewall recesses 120 may extend 15%, or 22 microns.

The first processing cycle and the second processing cycle of FIG. 8 may be executed in a similar or same manner as one another, but with variations therebetween with respect to process parameters chosen. For example, a processing time, flow rate, and/or power level for one or more of the deposition (806), first etch (808), and/or second etch (810) of the first processing cycle may be different from a processing time, flow rate, and/or source power level of one or more of the deposition (814), first etch (816), and/or second etch (818) of the second processing cycle.

For example, both deposition steps (806, 814) may be performed using C₄F₈ gas, and the various etching processes (808, 810, 816, 818) may be performed using SF₆. However, a flow rate (e.g., measured in standard cubic centimeter per minute, or sccm) of the etch 810 may be lower than a corresponding flow rate of the etch 818. For example, the flow rate of the etch 810 may be in a range of 290-310 sccm, while the flow rate of the etch 818 may be 500 sccm. Additionally, or alternatively, a time window for etching during the etch 810 may be, e.g., 4-5 seconds, while a time window for etching during the etch 818 may approximately twice as long or more, e.g., 8-11 seconds. Thus, an isotropic etching time, isotropic etching flow rate, and/or isotropic power level of the isotropic etch (810) of the first processing cycle may be less than an isotropic etching time, isotropic etching flow rate, and/or isotropic power level of the isotropic etch (818) of the second processing cycle.

In the example of FIG. 8, and other examples described herein, the DRIE process used for the first processing cycle and the second processing cycle may be implemented as follows. However, it will be appreciated that other variations may also be used.

For example, the DRIE process may be implemented in a manner(s) that enables process control to obtain relatively large swings in pressures, flows, and power, in relatively short times, and with loop lengths on the order of seconds.

For example, a processing cycle may include a deposition step of a polymer/passivation layer as C₄F₈→(CF₂)ₙ), followed by selective polymer/passivation layer removal from a horizontal surface at a bottom of a dicing channel during a first (anisotropic) etch using SF₆, which is followed by a second (isotropic) etch, e.g., a high-rate, isotropic etch of Si using SF₆. In this way, an anisotropic profile may be obtained.

In more detailed examples, the deposition step of the processing cycle may provide polymer passivation as a Teflon-like film (e.g., polymer chain), in which no radio frequency (RF) bias, in a lower pressure regime (e.g., approximately 35-45 mTorr, e.g., 40 mTorr) results in isotropic deposition of the film.

Then, the first etch may use SF 6 for selective polymer removal, with a high RF bias applied to assist in physical sputtering to remove polymer material from horizontal surface(s), and with a similar pressure regime to that just described for the deposition step.

Then, the second etch of the processing cycle may use SF₆ for high rate chemical etching, e.g., of Si (e.g., Si reacts with SF₆ to form SiF₄). This second etch may be executed with relatively high flow rates (e.g., hundreds of sccm), high pressure (200 mTorr or more), and high power (e.g., 3 kW or more). Removing RF bias ensures high selectivity with respect to remaining mask material, with an etch rate in a range of tens of microns/minute that is dependent on factors such as channel width, die size, and wafer thickness.

Thus, the second etch may isotropically remove, e.g., silicon substrate by suitable chemical reactions (e.g., (SF6+e→SF5+F+e, Si+F→SiF↑). As described, such a second etch is not typically able to remove remaining portions of the passivation layer, since, e.g., and as referenced above, the second etch does not typically use a RF bias power (in order to ensure high selectivity to the passivation layer).

The relatively wide and/or deep sidewall recesses 121 may define a length 610 of FIG. 6 that is defined between an end point of the sidewall recesses 120 and the back metal 606. Therefore, in the examples just given, the length 610 may consume 75%, 80%, 85%, or 90% of an overall thickness 608, 610 of a semiconductor wafer. Consequently, depending on a value of the overall thickness 608, 610, and the length 608, the second processing cycle may require, e.g., 85-95 iterations, or loops.

For example, Optical Emission Spectroscopy (OES) may be used to provide process control for obtaining a suitable endpoint, e.g., for executing a suitable number of iterations, or loops, of the second processing cycle. In specific implementations, OES may monitor light emitted by the plasma being used for the singulation; process endpoints may be determined based on changes in emission wavelengths of various etch by-products and/or gasses as the etch reaches a new layer(s).

An apparatus configured to implement the techniques described herein may include at least a plasma chamber that includes a mounting chuck or other suitable mounting hardware configured to receive a wafer such as shown in FIG. 3, and further configured to implement the die singulation techniques described herein. For example, the plasma chamber may include, or be associated with, suitable circuitry, hardware (e.g., at least one processor, and at least one memory), and/or associated software (e.g., instructions stored using the at least one memory and executed using the at least one processor) for controlling the various process parameters described herein, including, e.g., flow rate, pressure, power, RF bias, OES, and other parameters for controlling the described deposition and etching processes described herein, and variations thereof. For example, such control hardware and associated software may be programmable to designate one or more recipes controlling the above-referenced processing cycles. In this way, one or more wafers may be singulated using existing, selectable recipes designed to provide desired singulation results with respect to the described sidewall recesses, in a fast, efficient process(es) that facilitate optimized wafer throughput, while providing the various features and advantages described herein.

As shown in FIG. 6, the sidewall recesses 121 in and approaching a vicinity of the back metal 606 may be ill-formed, depending on an overall thickness of the wafer being singulated. For example, at such locations, the passivation layer thickness may be reduced during the deposition step (814), resulting in more undesired lateral etching than typically occurs closer to the device-side surface of the semiconductor die.

By selecting and configuring the differences in process parameters between the first processing cycle and the second processing cycle, desired characteristics of the sidewall recesses 120, 121 may be obtained. For example, desired absolute or relative values for the width, depth, or volume of the sidewall recesses 120, 121 may be obtained. For example, the sidewall recesses 121 may be formed having a width and/or depth at least twice that of the sidewall recesses 120. For example, the sidewall recesses 121 may have a width and/or depth of at least 2 microns, while the sidewall recesses 120 may have a width and/or depth of at most 1 micron.

Using the techniques described herein, increases in reliability of semiconductor die may be achieved, by ensuring a very low quantity of carbon and fluoride polymer contaminants on die sidewalls. A risk of fragility of a device-side surface above the sidewall recesses may be reduced, since the described first sidewall recesses 120 provide less of an undercut of the device-side surface than conventional sidewall recesses. Similarly, the undercut reduction increases an active area of the semiconductor die; e.g., but four microns or more on each side of the die. Additionally, as less solvent/rinse time is required, reductions in associated costs may be achieved, as well.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A method of making a semiconductor die, comprising:
forming a first plurality of sidewall recesses in a sidewall of a substrate and extending along a first length of the sidewall from a first surface of the substrate, the first plurality of sidewall recesses each having less than a first depth, wherein the forming the first plurality of sidewall recesses results in first residual contaminants formed in at least a portion of the first plurality of sidewall recesses;
forming a second plurality of sidewall recesses in the sidewall of the substrate and extending along a second length of the sidewall between the first plurality of sidewall recesses and a second surface of the substrate, the second plurality of sidewall recesses each defining at least a second depth that is greater than the first depth, wherein the forming the second plurality of sidewall recesses results in second residual contaminants formed in at least a portion of the second plurality of sidewall recesses,
the semiconductor die being singulated by the forming of the second plurality of sidewall recesses upon reaching the second surface of the substrate; and
removing the first residual contaminants and the second residual contaminants therefrom.

2. The method of claim 1, wherein forming the first plurality of sidewall recesses comprises performing a first processing cycle with first process parameters, and further wherein forming the second plurality of sidewall recesses comprises performing a second processing cycle with second process parameters.

3. The method of claim 2, wherein the first processing cycle and the second processing cycle include a deposition of a passivation layer, an anisotropic etch, and an isotropic etch, wherein at least a portion of the passivation layer is included in the first residual contaminants and/or the second residual contaminants.

4. The method of claim 3, wherein the first process parameters include an isotropic etching time that is less than an isotropic etching time of the second process parameters.

5. The method of claim 3, wherein the first process parameters include an isotropic etching flow rate that is less than an isotropic etching flow rate of the second process parameters.

6. The method of claim 3, wherein the first process parameters include an isotropic etching power level that is less than an isotropic etching power level of the second process parameters.

7. The method of claim 1, further comprising:
mounting the substrate on carrier tape prior to forming the first plurality of sidewall recesses and the second plurality of sidewall recesses;
moving the semiconductor die, on the carrier tape, to a cleaning chamber; and
performing the removing of the semiconductor die while the semiconductor die is attached to the carrier tape.

8. The method of claim 7, wherein the removing comprises rinsing the semiconductor die using a solvent spray.

9. The method of claim 1, comprising:
forming the first plurality of sidewall recesses each with less than a first width; and
forming the second plurality of sidewall recesses each with at least a second width that is greater than the first width.

10. The method of claim 1, comprising:
forming a third plurality of sidewall recesses in the sidewall of the substrate and extending along a third length of the sidewall between the first plurality of sidewall recesses and the second plurality of sidewall recesses, the third plurality of sidewall recesses each defining at least a third depth that is between the first depth and the second depth.

11. A method of performing semiconductor die singulation, comprising:
mounting a substrate attached to carrier tape on a mounting chuck;
defining a dicing channel in the substrate;
forming a first plurality of sidewall recesses in sidewalls of the dicing channel and extending along a first length of the sidewalls from a first surface of the substrate, the first plurality of sidewall recesses each defining less than a first depth;
forming a second plurality of sidewall recesses in the sidewalls of the dicing channel and extending along a second length of the sidewalls between the first plurality of sidewall recesses and a second surface of the substrate that is attached to the carrier tape, the second plurality of sidewall recesses each defining at least a second depth that is greater than the first depth;
determining that the forming of the second plurality of sidewall recesses has reached the carrier tape, to thereby define a first die and a second die;
transitioning the first die and the second die on the carrier tape to a cleaning chamber;
removing contaminants from the first plurality of sidewall recesses and the second plurality of sidewall recesses of the first die and the second die; and
removing the first die and the second die from the carrier tape.

12. The method of claim 11, wherein forming the first plurality of sidewall recesses comprises performing a first processing cycle with first process parameters, and further wherein forming the second plurality of sidewall recesses comprises performing a second processing cycle with second process parameters.

13. The method of claim 12, further comprising:
implementing the first process parameters and the second process parameters based on a first quantity of the contaminants in the first plurality of sidewall recesses and on a second quantity of the contaminants in the second plurality of sidewall recesses.

14. The method of claim 12, wherein the first processing cycle and the second processing cycle include a deposition of a passivation layer, an anisotropic etch, and an isotropic etch, wherein at least a portion of the passivation layer is included in the contaminants.

15. The method of claim 11, wherein the removing comprises rinsing the first die and the second die using a solvent spray to remove the contaminants.

16. The method of claim 11, further comprising:
forming the first plurality of sidewall recesses each with less than a first width; and
forming the second plurality of sidewall recesses each with at least a second width that is greater than the first width.

17. A method of performing semiconductor die singulation, comprising:
mounting a substrate attached to carrier tape on a mounting chuck;
defining a dicing channel in the substrate;
forming a first plurality of sidewall recesses in sidewalls of the dicing channel and extending along a first length of the sidewalls from a first surface of the substrate, the first plurality of sidewall recesses each defining less than a first depth, wherein the forming the first plurality of sidewall recesses results in first residual contaminants formed in at least some of the first plurality of sidewall recesses;
forming a second plurality of sidewall recesses in the sidewalls of the dicing channel and extending along a second length of the sidewalls between the first plurality of sidewall recesses and a second surface of the substrate that is attached to the carrier tape, the second plurality of sidewall recesses each defining at least a second depth that is greater than the first depth, wherein the forming the second plurality of sidewall recesses results in second residual contaminants formed in at least some of the second plurality of sidewall recesses;
determining that the forming of the second plurality of sidewall recesses has reached the carrier tape, to thereby define a first die and a second die;
transitioning the first die and the second die on the carrier tape to a cleaning chamber;
rinsing the first residual contaminants from the first plurality of sidewall recesses and the second residual contaminants from the second plurality of sidewall recesses of the first die and the second die using a solvent spray; and
removing the first die and the second die from the carrier tape.

18. The method of claim 17, wherein forming the first plurality of sidewall recesses comprises performing a first processing cycle with first process parameters, and further wherein forming the second plurality of sidewall recesses comprises performing a second processing cycle with second process parameters.

19. The method of claim 18, wherein the first processing cycle and the second processing cycle include a deposition of a passivation layer, an anisotropic etch, and an isotropic etch, wherein at least a portion of the passivation layer is included in the first residual contaminants and/or the second residual contaminants.

20. The method of claim 17, further comprising:
forming the first plurality of sidewall recesses each with less than a first width; and
forming the second plurality of sidewall recesses each with at least a second width that is greater than the first width.
